(19) United States
(12) Patent Application Publication
(10) Pub. No.: US 2017/0194955 A1
(43) Pub. Date: Jul. 6, 2017

(54) Dynamic Snubber Switch for AC Load Side Application

(71) Applicants: Ronald J. Gumina, Mandeville, LA (US); Michael T. Dewenter, New Orleans, LA (US)

(72) Inventors: Ronald J. Gumina, Mandeville, LA (US); Michael T. Dewenter, New Orleans, LA (US)

(21) Appl. No.: 14/986,137

(22) Filed: Dec. 31, 2015

(51) Int. Cl. H03K 17/0814; H03K 17/785; H05B 33/08

(52) U.S. Cl. CPC H03K 17/08146; H05B 33/0815; H05B 33/0845; H03K 17/785; H03K 17/08142

(57) ABSTRACT

Triac controlled dimmers and switches often employ a snubber circuit to prevent self-tripping and to reduce radio frequency emissions. Standard snubber circuits allow small amounts of AC current to reach the load even when the dimmer or switch is set to the off position, thereby causing unwanted illumination in certain high efficiency LED lighting. A load-side dynamic snubber circuit is provided for use in dimmers, switches, and similar applications which only activates the snubber circuit when the dimmer or switch is active, thereby preventing current from reaching the load when the dimmer or switch is in the off position.

### BACKGROUND OF THE INVENTION

I. Field

The present invention relates to an improved snubber circuit for use in certain electric switches and dimmers.

II. Background

In Triac controlled lamp dimmers, a snubber circuit is often used to prevent the Triac from self-triggering as well as to reduce emitted radio-frequency (RF) noise. Reduction of RF noise is of special concern where the snubber circuit is used across a relay switching heavy loads. Standard snubber circuits, such as those used in dimmers and switches, commonly consist of standard resistive and capacitive elements placed in parallel to the Triac or relay in question. However, these configurations allow a small amount of AC current to pass through and be present on the load even when the Triac or relay is de-energized. This current, although small, is sometimes enough to illuminate some high-efficiency LED lighting, despite the fact that the dimmer or switch is “off” and should not allow for illumination of said LED light.

There is a need for an improved snubber circuit that prevents current from reaching a load even when the Triac or relay associated with said circuit is de-energized.

### SUMMARY OF THE INVENTION

The present invention meets this and other needs by providing, among other things, techniques for providing a load-side dynamic snubber circuit for use in various devices, including various dimmers and switches.

An exemplary embodiment of the invention provides a switching device comprising a gate device, a snubber circuit, and a controller. In said embodiment, said gate device is connected in series with said snubber circuit, and said controller is connected to said gate device. Further, said controller is configured to send a first signal to said gate device when said switching device is in a first state, thereby causing said gate device to enter a first state, where said first state of said gate device allows electrical current to flow through said gate device and said snubber circuit. Additionally, said controller is configured to send a second signal to said gate device when said switching device is in a second state, thereby causing said gate device to enter a second state, where said second state of said gate device prevents electrical current from flowing through said gate device and said snubber circuit.

In another exemplary embodiment, a switching device is provide comprising a first terminal and a second terminal, wherein said first terminal is configured to connect to an AC voltage source and said second terminal is configured to connect to a load. Said device further comprises a user interface, a gate device (where said gate device comprises a first terminal, a second terminal and a control terminal), a snubber circuit, and a controller, wherein said first terminal of said gate element is connected to said first terminal of said switching device, said second terminal of said gate element is connected to said snubber circuit, and said control terminal of said gate element is connected to said controller. In said embodiment, said controller is configured to monitor a state of said user interface, and said first terminal of said switching device, said gate element, said snubber circuit, and said second terminal of said switching device are connected in series. Furthermore, said controller is configured to send a first signal to said gate device when said user interface is in a first state, thereby causing said gate device to enter a first state, wherein said first state of said gate device allows electrical current to flow through said gate device and said snubber circuit to said load; and said controller is configured to send a second signal to said gate device when said user interface is in a second state, thereby causing said gate device to enter a second state, wherein said second state of said gate device prevents electrical current from flowing through said gate device and said snubber circuit to said load.

In an exemplary embodiment, said switching device is a dimmer. In another exemplary embodiment, said switching device is a switch.

The images in the drawings are simplified for illustrative purposes and are not depicted to scale. To facilitate understanding, identical reference numerals have been used, where possible, to designate identical elements that are common to the Figures, except that suffixes may be added, when appropriate, to differentiate such elements.

The appended drawings illustrate exemplary configurations of the invention and, as such, should not be considered as limiting the scope of the invention that may admit to other equally effective configurations. It is contemplated that features of one configuration may be beneficially incorporated in other configurations without further recitation. The above and other objects and features of the present invention will become apparent from the drawings, the description given herein, and the appended claims.

### BRIEF DESCRIPTION OF THE DRAWINGS

For a further understanding of the nature and objects of the present invention, reference should be had to the following description taken in conjunction with the accompanying drawings in which like parts are given like reference numerals.

FIG. 1 illustrates a load-side dynamic snubber circuit implemented as part of a dimmer.

FIG. 2 illustrates a load-side dynamic snubber circuit implemented as part of a switch.

FIG. 3 illustrates a load-side dynamic snubber circuit implemented as part of a dimmer, where an opto-isolated MOSFET solid-state relay is used in lieu of a Triac.

FIG. 4 illustrates a load-side dynamic snubber circuit implemented as part of a switch, where an opto-isolated MOSFET solid-state relay is used in lieu of a Triac.

FIG. 5 illustrates a timing diagram graphically depicting the logic used to control a dimmer comprising a load-side dynamic snubber circuit.

FIG. 6 illustrates a timing diagram graphically depicting the logic used to control a switch comprising a load-side dynamic snubber circuit.

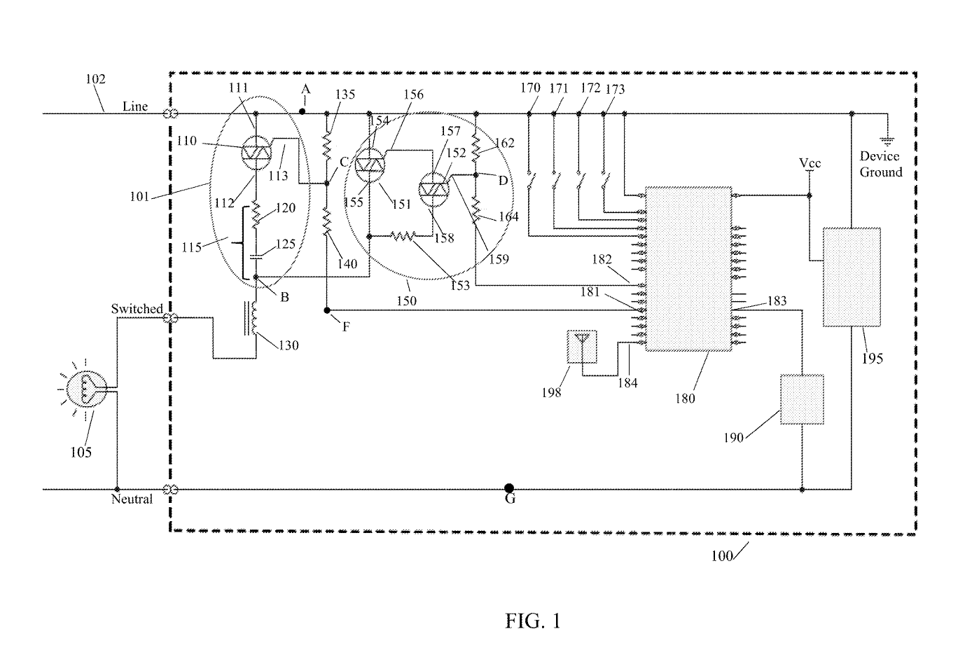

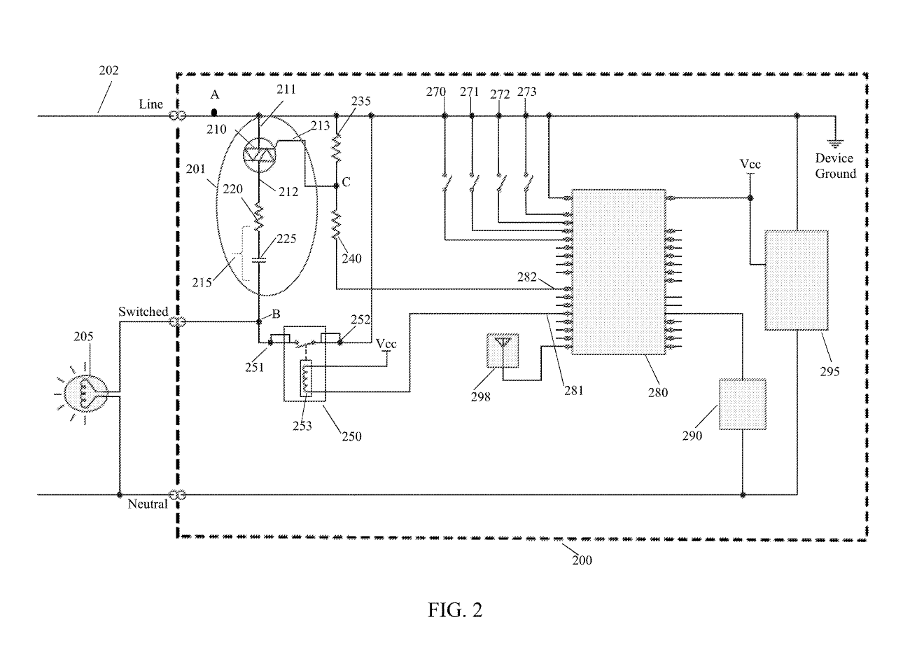

The images in the drawings are simplified for illustrative purposes and are not depicted to scale. Within the descriptions of the figures, similar elements are provided similar names and reference numerals as those of the previous figure(s). Where a later figure utilizes the same element or a similar element in a different context or with different functionality, the element is provided a different leading numeral representative of the figure number (e.g., 1xx for FIG. 1 and 2xx for FIG. 2). The specific numerals assigned to the elements are provided solely to aid in the description and are not meant to imply any limitations (structural or functional) on the invention.

The appended drawings illustrate exemplary configurations of the invention and, as such, should not be considered as limiting the scope of the invention that may admit to other equally effective configurations. It is contemplated that features of one configuration may be beneficially incorporated in other configurations without further recitation.

### DETAILED DESCRIPTION

The word “exemplary” is used herein to mean “serving as an example, instance, or illustration.” Any configuration or design described herein as “exemplary” is not necessarily to be construed as preferred or advantageous over other configurations or designs.

The present invention solves the problem of inadvertent current passing through to a load even when a dimmer or switch is de-energized by providing a load-side dynamic snubber circuit. FIG. 1 shows an exemplary embodiment of the present invention implemented in a dimmer, wherein dimmer 100 includes a dynamic snubber circuit 101. Dynamic snubber circuit 101 comprises a microprocessor-controlled Triac 110 in series with snubber circuit 115, where snubber circuit 115 is comprised of resistor 120 connected in series with capacitor 125. This arrangement allows for selective activation of snubber circuit 115.

More specifically, dimmer 100 comprises dynamic snubber control Triac 110, wherein terminal 111 of Triac 110 is connected to node A (where node A is connected to AC voltage source 102), terminal 112 of Triac 110 is connected to a first terminal of resistor 120, and gate 113 of Triac 110 is connected to node C. A second terminal of resistor 120, which is connected in series with terminal 112 of Triac 110, is connected to a first terminal of capacitor 125; and, a second terminal of capacitor 125 is connected to node B. In an exemplary embodiment, AC voltage source 102 is a typical residential 120 V AC power supply, resistor 120 has a resistive value of 1000Ω, and capacitor 125 has a capacitance of 0.01 μF. In the embodiment depicted in FIG. 1, node A is shown as being connected to “device ground” simply as a reference voltage and not to signify any connection to any external grounding point.

Also in series with Triac 110, resistor 120, and capacitor 125 is inductive element 130, wherein a first terminal of inductor 130 is connected to node B, and a second terminal of inductor 130 is connected to the switched load 105. In an exemplary embodiment, inductor 130 has a value of 23 μH.

Also connected with Triac 110 are resistors 135 and 140, where a first terminal of resistor 135 is connected to node A, and a second terminal of resistor 135 is connected to node C; and, where a first terminal of resistor 140 is connected to node C and a second terminal of resistor 140 is connected to node F. Node C is also connected directly to gate terminal 113. Node F is connected to output port 181 of microcontroller 180. In an exemplary embodiment, resistor 135 has a value of 10,000Ω, resistor 140 has a value of 620Ω, and microcontroller 180 is a STM Microcontroller model STM8L1013T6.

In parallel with dynamic snubber circuit 101 is main dimming Triac circuit 150, comprising Triac 151, Triac 152 and resistor 153. Terminal 154 of Triac 151 is connected to node A, terminal 155 of Triac 151 is connected to node B, and gate terminal 156 of Triac 151 is connected to terminal 157 of Triac 152. Terminal 158 of Triac 152 is connected to a first terminal of resistor 153, and a second terminal of resistor 153 is connected to node B. In an exemplary embodiment, resistor 153 has a value of 200Ω. It would be understood to a person of skill in the art that main dimming Triac circuit 150 may be replaced by any comparable dimming circuit capable of limiting the amount of power delivered to a load based on the state of the dimmer input.

Gate terminal 159 of Triac 152 is connected to node D, where node D is connected to a first terminal of resistor 162 and a first terminal of resistor 164. A second terminal of resistor 162 is connected to node A, and a second terminal of resistor 164 is connected to output 182 of microcontroller 180. In an alternative embodiment (not shown), Triac 151 is controlled by a microcontroller different from the microcontroller controlling Triac 110. In an exemplary embodiment, resistor 162 has a value of 10,000Ω, and resistor 164 has a value of 330Ω.

Dimmer 100 further comprises switches 170, 171, 172 and 173, wherein said switches can be programmed to perform various functions. For example, in an exemplary embodiment, switch 170 is a hard on/off switch which bypasses the dimmer functionality. In another embodiment, switch 171 is a toggle which reverses the functionality of the dimmer (i.e., reversing the direction of brightness versus dimness controlled by a given manipulation of dimmer 100). In other embodiments, these switches may serve other functions; or, alternatively, said switches may be disabled or omitted from the device.

Dimmer 100 further comprises zero-crossing detector 190, the input of which is connected to the AC power system neutral, where said detector 190 detects when the AC power waveform has an amplitude of zero volts. In the embodiment shown in FIG. 1, the output of detector 190 is connected to input 183 of microcontroller 180. Dimmer 100 further comprises internal DC power supply 195.

In an exemplary embodiment, dimmer 100 further comprises radio frequency transceiver 198, which is connected to input/output port 184 of microcontroller 180 and which allows for radio frequency remote control of dimmer 100. It is also understood that dimmer 100 includes a user interface (not shown) whereby a user can adjust the amount of power delivered to the load by dimmer 100, where such user interface could be a knob, slider, toggle, or any digital equivalent which allows for variation in the amount of power allowed to pass through the dimmer 100 to load 105.

FIG. 2 shows an implementation of a dynamic snubber circuit in a microprocessor-controlled switch (as compared to the dimmer shown in FIG. 1). Switch 200 is essentially identical to dimmer 100, except that switch 200 lacks components comparable to main dimming Triac circuit 150, and instead includes relay 250. Just as in FIG. 1, dynamic snubber circuit 201 comprises a microprocessor-controlled Triac 210 in series with snubber circuit 215, where snubber circuit 215 is comprised of resistor 220 connected in series with capacitor 225.

Specifically, switch 200 includes dynamic snubbing circuit 201, which circuit comprises Triac 210, wherein terminal 211 of Triac 210 is connected to node A (where node A is connected to AC voltage source 202), terminal 212 of Triac 210 is connected to a first terminal of resistor 220, and gate 213 of Triac 210 is connected to node C. A second terminal of resistor 220, which is connected in series with terminal 212 of Triac 210, is connected to a first terminal of capacitor 225; and, a second terminal of capacitor 225 is connected to node B. In an exemplary embodiment, AC voltage source 202 is a typical residential 120 V AC power supply, resistor 220 has a resistive value of 1000Ω, and capacitor 225 has a capacitance of 0.01 μF. In the embodiment depicted in FIG. 2, node A is shown as being connected to “device ground” simply as a reference voltage, and not to signify any connection to any external grounding point.

Also connected with Triac 210 are resistors 235 and 240, where a first terminal of resistor 235 is connected to node A, and a second terminal of resistor 235 is connected to node C; and, where a first terminal of resistor 240 is connected to node C and a second terminal of resistor 240 is connected to microcontroller 280 at output port 282. Node C is also connected directly to gate terminal 213. In an exemplary embodiment, resistor 235 has a value of 10,000Ω, resistor 240 has a value of 620Ω, and microcontroller 280 is a STM Microcontroller model STM8L1013T6.

Switch 200 further comprises relay 250, where a first terminal 251 of relay 250 is connected to node B (which is also connected to switched load 205), a second terminal 252 of relay 250 is connected to node A, and activation coil 253 of relay 250 is connected to output 281 of microcontroller 280. Note that particular output ports of the microcontroller shown in each embodiment described herein may vary from embodiment to embodiment, and it would be known to a person of skill in the art that the output ports of such a microcontroller are generally configurable.

Switch 200 further comprises: switches 270, 271, 272 and 273 which are similar to switches 170-173 described above; zero-crossing detector 290, which is similar to zero-crossing detector 190 described above; internal power supply 295, which is similar to internal power supply 195 described above; and, radio frequency transceiver 298, which is similar to radio frequency transceiver 198 described above.

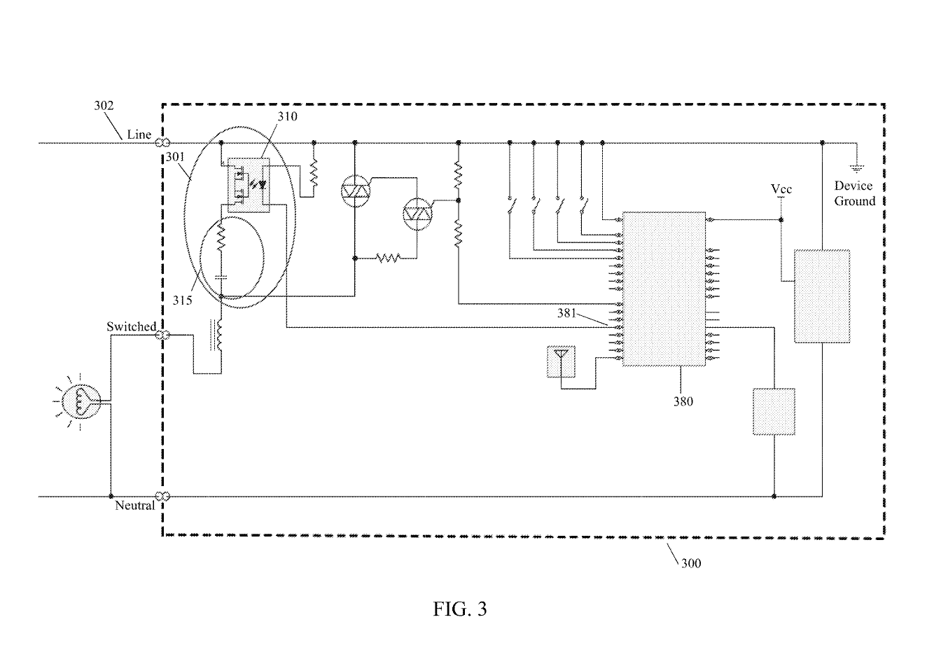

FIG. 3 shows an alternative embodiment of a dynamic snubber circuit implemented in a dimmer. Specifically, dimmer 300 is similar to dimmer 100, except that instead of using a Triac (such as Triac 110) to dynamically activate snubber circuit 315, dimmer 300 instead uses opto-isolated MOSFET solid-state relay 310, where relay 310 is controlled by output 381 of controller 380.

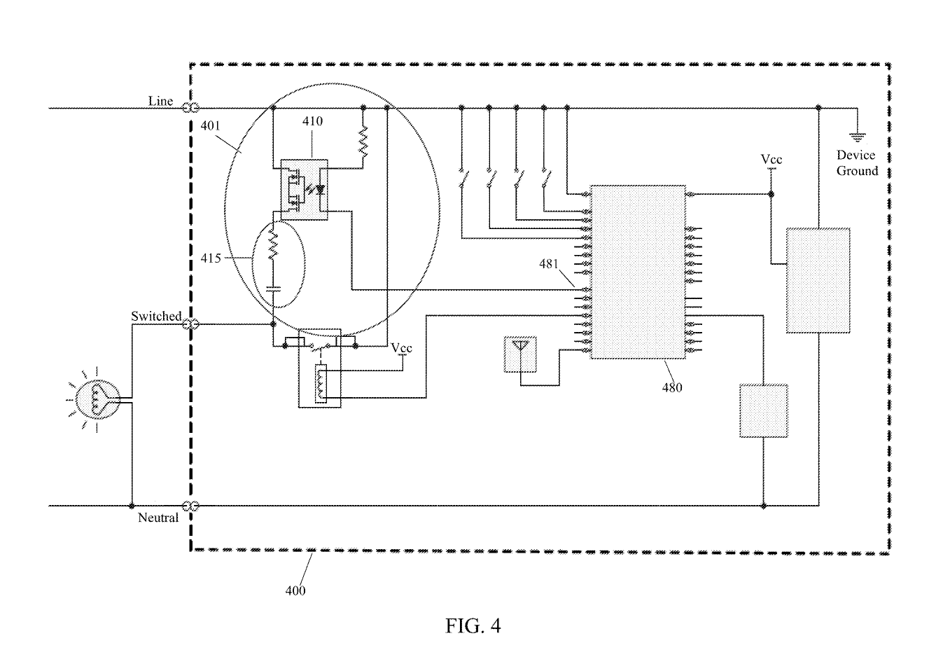

Similarly, FIG. 4 shows an alternative embodiment of a dynamic snubber circuit implemented in a switch. Specifically, switch 400 is similar to switch 200, except that instead of using a Triac (such as Triac 210) to dynamically activate snubber circuit 415, switch 400 instead uses opto-isolated MOSFET solid-state relay 410, where relay 410 is controlled by output 481 of controller 480.

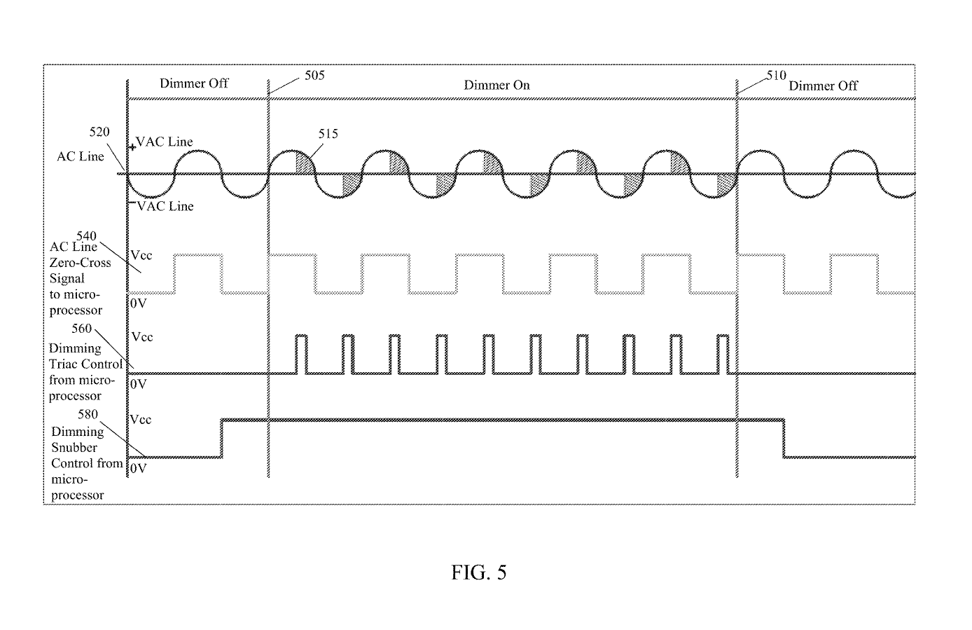

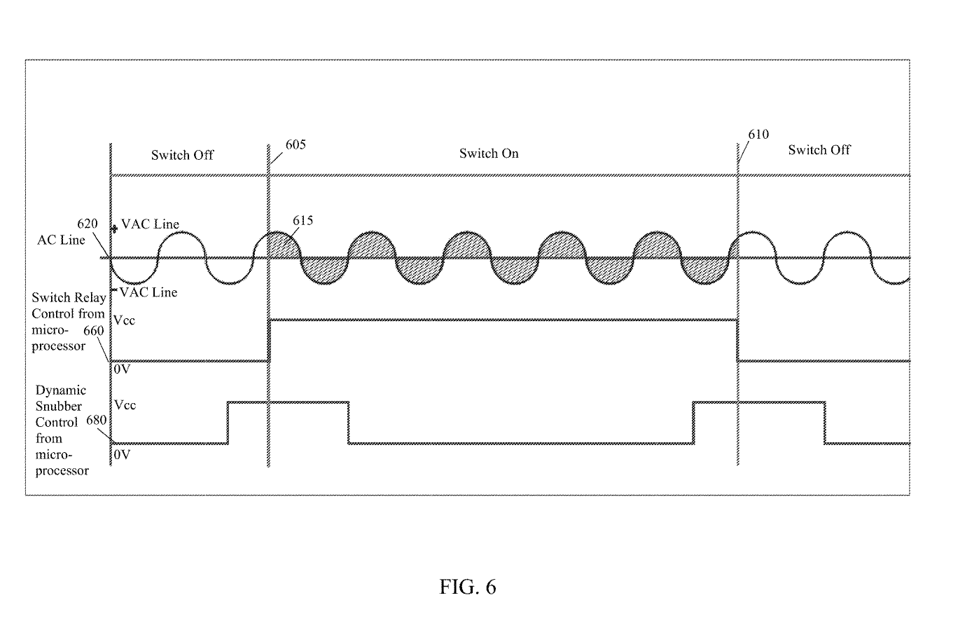

FIGS. 5 and 6 shown timing diagrams which graphically demonstrate the logic used by the microcontroller to control the dimmers and switches described above, respectively.

FIG. 5 shows a timing diagram depicting logic associated with the operation of dimmers 100 and 300 (for the remainder of the description of FIG. 5, FIG. 1 will be referenced, but the description applies equally to the embodiment shown in FIG. 3). Line 520 shows the 120 V AC line voltage, such as that provided by voltage source 102. Demarcation line 505 shows the point in time where the dimmer is “activated” (for example, the dimmer is manipulated by a user, via a user interface, to activate load 105). Shaded areas 515 show the portion of the V AC cycle wherein the dimmer allows power to reach load 105, thereby “dimming” the light provided by said load. Line 540 shows the output of zero-cross detector 190, which is connected to microcontroller input 183. Line 560 shows output 182 of microcontroller 180 which controls main dimming Triac circuit 150. Finally, line 580 shows output 181 of microcontroller 180 which controls Triac 110, thereby controlling dynamic snubber circuit 115.

Further referencing the logic depicted in FIG. 5, when dimmer 100 is in the “off” state (i.e., the load 105 should not receive any power and thus not illuminate), both the main switching Triac 151 and the dynamic snubber Triac 110 are in the “off” state (i.e., no current passes through either Triac). When dimmer 100 is switched to the “on” state, the dynamic snubber Triac 110 is switched “on” by the microprocessor at least one AC cycle (16 msec) prior to the start of the operation of Triac 151. While dimmer 100 remains in the “on” state, the dynamic snubber Triac 110 remains “on”. When dimmer 100 is switched “off”, the dynamic snubber Triac 110 is switched “off” at least one AC cycle (16 msec) after Triac 151 in the “off” state. While not shown, in ah alternative embodiment, the microcontroller may also be configured to periodically energize the dynamic snubber Triac 110 for short periods of time (for example, 16 msec) in the event that inductive or capacitive loads trigger Triac 110 or Triac 151.

FIG. 6 shows a timing diagram depicting logic associated with the operation of switches 200 and 400 (for the remainder of the description of FIG. 6, FIG. 2 will be referenced, but the description applies equally to the embodiment shown in FIG. 4). Line 620 shows the 120 V AC line voltage, such as that provided by voltage source 202. Demarcation line 605 shows the point in time where the switch is “activated” (for example, the switch is manipulated by a user, via a user interface, to activate load 205). Shaded areas 615 show the portion of the V AC cycle wherein the switch allows power to reach load 205 (so, as opposed to dimmer 100, switch 200 allows power to reach the load the entire time the switch is “on”). Line 660 shows output 281 of microcontroller 280 which controls relay 250. Finally, line 680 shows output 282 of microcontroller 280 which controls Triac 210, thereby controlling dynamic snubber circuit 215.

Further referencing the logic depicted in FIG. 6, when switch 200 is turned “on” or “off”, the dynamic snubber Triac 210 is turned on at least one AC cycle (16 msec) prior to the state change of relay 250. Once the state of relay 250 has changed, either from on to off or vice-versa, the dynamic snubber Triac 210 is de-energized at least one AC cycle (16 msec) after relay 250 has finished changing state.

For the purposes of this application, the term “gate element” means a Triac, an opto-isolated MOSFET solid-state relay, electromechanical relay, or any other device which can serve as a dynamic switch allowing or preventing the passage of electrical current along a given circuit path based on a control signal input to said device (where said control signal can be electrical, optical, or any other form of control signal regardless of the communication medium).

For the purposes of this application, when components or nodes are referred to as being “connected” or “connected in series”, such connection may include one or more intervening components.

In one or more exemplary configurations, one or more of the functions described may be implemented in hardware, software, firmware, or any combination thereof.

The previous description of the disclosed configurations is provided to enable any person skilled in the art to make or use the disclosure. Various modifications to these configurations will be readily apparent to those skilled in the art, and the generic principles defined herein may be applied to other configurations without departing from the spirit or scope of the disclosure. Thus, the disclosure is not intended to be limited to the configurations shown herein but is to be accorded the widest scope consistent with the principles and novel features disclosed herein.

What is claimed is:

1. A switching device comprising:
a gate device;
a snubber circuit; and
a controller;
wherein said gate device is connected in series with said snubber circuit, and wherein said controller is connected to said gate device; and
wherein said controller is configured to send a first signal to said gate device when said switching device is in a first state, thereby causing said gate device to enter a first state, wherein said first state of said gate device allows electrical current to flow through said gate device and said snubber circuit; and
wherein said controller is configured to send a second signal to said gate device when said switching device is in a second state, thereby causing said gate device to enter a second state, wherein said second state of said gate device prevents electrical current from flowing through said gate device and said snubber circuit.

2. The switching device of claim 1, further comprising a dimmer circuit, wherein said dimmer circuit is connected in parallel with said gate device and said snubber circuit, wherein said dimmer circuit is connected to said controller, and wherein said controller is configured to receive a user input and to control said dimmer circuit based on said user input.

3. The switching device of claim 2, wherein said gate device is a Triac.

4. The switching device of claim 2, wherein said gate device is an opto-isolated MOSFET solid-state relay.

5. The switching device of claim 1, further comprising a relay, wherein said relay is connected in parallel with said gate device and said snubber circuit, wherein said relay is also connected to said controller, and wherein said controller is configured to receive a user input and to control said relay based on said user input.

6. The switching device of claim 5, wherein said gate device is a Triac.

7. The switching device of claim 5, wherein said gate device is an opto-isolated MOSFET solid-state relay.

8. The switching device of claim 1, wherein said snubber circuit comprises a resistor and a capacitor connected in series.

9. A switching device comprising:
a first terminal and a second terminal, wherein said first terminal is configured to connect to an AC voltage source and said second terminal is configured to connect to a load;
a user interface;
a gate device, said gate device comprising a first terminal, a second terminal and a control terminal;
a snubber circuit; and
a controller;
wherein said first terminal of said gate element is connected to said first terminal of said switching device, said second terminal of said gate element is connected to said snubber circuit, and said control terminal of said gate element is connected to said controller;
wherein said controller is configured to monitor a state of said user interface;
wherein said first terminal of said switching device, said gate element, said snubber circuit, and said second terminal of said switching device are connected in series;
wherein, said controller is configured to send a first signal to said gate device when said user interface is in a first state, thereby causing said gate device to enter a first state, wherein said first state of said gate device allows electrical current to flow through said gate device and said snubber circuit to said load; and
wherein said controller is configured to send a second signal to said gate device when said user interface is in a second state, thereby causing said gate device to enter a second state, wherein said second state of said gate device prevents electrical current from flowing through said gate device and said snubber circuit to said load.

10. The device of claim 9, further comprising a dimmer circuit, wherein said dimmer circuit is connected in parallel with said gate device and said snubber circuit, wherein said dimmer circuit is connected to said controller, and wherein said controller is configured to receive a user input from said user interface and to control said dimmer circuit based on said user input.

11. The switching device of claim 10, wherein said gate device is a Triac.

12. The switching device of claim 10, wherein said gate device is an opto-isolated MOSFET solid-state relay.

13. The switching device of claim 9, further comprising a relay, wherein said relay is connected in parallel with said gate device and said snubber circuit, wherein said relay is also connected to said controller, and wherein said controller is configured to receive a user input from said user interface and to control said relay based on said user input.

14. The switching device of claim 13, wherein said gate device is a Triac.

15. The switching device of claim 13, wherein said gate device is an opto-isolated MOSFET solid-state relay.

16. The switching device of claim 9, wherein said snubber circuit comprises a resistor and a capacitor connected in series.

17. A switching device comprising:
a means for connecting said device to an AC power source;
a means for connecting said device to a load;
a user interface;
a snubber circuit, wherein said snubber circuit is connected in series with said means for connecting to an AC power source and said means for connecting to a load;
a means for controlling the flow of AC current through said snubber circuit; and
a controller connected to said user interface and said controlling means;
wherein, said controller is configured to send a first signal to said controlling means when said user interface is in a first state, thereby causing said controlling means to allow electrical current to flow through said snubber circuit to said load; and
wherein, said controller is configured to send a second signal to said controlling means when said user interface is in a second state, thereby causing said controlling means to prevent electrical current from flowing through said snubber circuit to said load.

18. The switching device of claim 17, further comprising a means for varying the amount of power delivered to said load, wherein said varying means is connected to said controller, and wherein said varying means is connected in parallel with said snubber circuit.
